(19) United States
(12) Patent Application Publication
(10) Pub. No.: US 2022/0350248 A1
(43) Pub. Date: Nov. 3, 2022

(54) METHOD OF FORMING AN ADHESION LAYER ON A PHOTORESIST UNDERLAYER AND STRUCTURE INCLUDING SAME

(71) Applicant: ASM IP Holding B.V., Almere (NL)

(72) Inventors: Zecheng Liu, Tokyo (JP); Takashi Yoshida, Tokyo (JP); Tomohiro Kubota, Tokyo (JP); Hideaki Fukuda, Tokyo (JP)

(21) Appl. No.: 17/724,457

(22) Filed: Apr. 19, 2022

Related U.S. Application Data
(60) Provisional application No. 63/178,038, filed on Apr. 22, 2021.

(51) Int. Cl. G03F 7/11; H01L 21/033; H01J 37/32; C23C 16/455; C23C 16/02; C23C 16/50; C23C 16/52

(52) U.S. Cl. CPC G03F 7/11; H01L 21/0337; H01J 37/3244; H01J 37/32724; H01J 37/32541; C23C 16/45536; C23C 16/45546; C23C 16/45529; C23C 16/45553; C23C 16/0272; C23C 16/50; C23C 16/52; H01L 21/0332; H01J 2237/332

(57) ABSTRACT

Methods of forming structures including a photoresist underlayer and an adhesion layer and structures including the photoresist underlayer and adhesion layer are disclosed. Exemplary methods include forming the photoresist underlayer and forming an adhesion layer using a cyclical deposition process. The adhesion layer can be formed within the same reaction chamber used to form the photoresist underlayer.

### CROSS-REFERENCE TO RELATED APPLICATIONS

This application claims the benefit of U.S. Provisional Application No. 63/178,038, filed on Apr. 22, 2021, in the United States Patent and Trademark Office, the disclosure of which is incorporated herein in its entirety by reference.

### FIELD OF INVENTION

The present disclosure generally relates to structures and to methods of forming structures using photoresist. More particularly, the disclosure relates to structures including or formed using a photoresist underlayer and to methods of forming such structures.

### BACKGROUND OF THE DISCLOSURE

During the manufacture of electronic devices, fine patterns of features can be formed on a surface of a substrate by patterning the surface of the substrate and etching material from the substrate surface using, for example, gas-phase etching processes. As a density of devices on a substrate increases, it becomes increasingly desirable to form features with smaller dimensions.

Photoresist is often used to pattern a surface of a substrate prior to etching. A pattern can be formed in the photoresist, by applying a layer of photoresist to a surface of the substrate, masking the surface of the photoresist, exposing the unmasked portions of the photoresist to radiation, such as ultraviolet light, and removing a portion (e.g., the unmasked or masked portion) of the photoresist, while leaving a portion of the photoresist on the substrate surface.

Recently, techniques have been developed to use extreme ultraviolet (EUV) wavelengths to develop patterns having relatively small pattern features (e.g., 10 nm or less). To form features on a substrate using EUV, a photoresist underlayer may be deposited onto a surface of a substrate, and then an EUV photoresist layer is deposited overlying the photoresist underlayer. Spin-on glass (SOG) is often used as an underlayer. The spin-on glass underlayer generally has a thickness of about 10 nm or more. More recently, plasma deposited oxides have been investigated as possible materials for photoresist underlayers. However, such oxides generally exhibit a higher surface polarity than the (e.g., EUV) photoresist. The difference in surface polarities can result in pattern collapse. For at least these reasons, improved structures including a photoresist underlayer, such as an underlayer suitable for use with EUV photoresist, and methods of forming such structures are desired.

Any discussion of problems and solutions set forth in this section has been included in this disclosure solely for the purpose of providing a context for the present disclosure and should not be taken as an admission that any or all of the discussion was known at the time the invention was made.

### SUMMARY OF THE DISCLOSURE

Various embodiments of the present disclosure relate to structures including photoresist underlayers and adhesion layers and to methods of forming the layers and structures. While the ways in which various embodiments of the present disclosure address drawbacks of prior methods and structures are discussed in more detail below, in general, various embodiments of the disclosure provide structures that can include a relatively thin, uniform photoresist underlayer with desired properties, such as desired etch selectivity, pattern quality, and/or pattern stability. Exemplary photoresist underlayers can be formed using a cyclical process, such as atomic layer deposition, which allows for precise control of a thickness of the photoresist underlayer—both on a surface of a substrate and from substrate to substrate. In addition, as set forth in more detail below, an additional adhesion layer can be formed to provide desired surface energy to promote desired adhesion between the photoresist underlayers and overlying photoresist.

In accordance with exemplary embodiments of the disclosure, a method of forming a structure comprising a photoresist underlayer includes providing a substrate within a reaction chamber, forming a photoresist underlayer overlying a surface of the substrate, and forming an adhesion layer overlying the photoresist underlayer. The adhesion layer can be interposed between and in contact with both the photoresist underlayer and a photoresist layer. Examples of the disclosure can further include forming the (e.g., EUV) photoresist layer overlying the adhesion layer. The adhesion layer can be formed using a first cyclic deposition process that includes providing a silicon precursor to the reaction chamber, providing an inert gas into the reaction chamber, and forming a plasma using the inert gas to form activated species that react with the silicon precursor or a derivative thereof to form the adhesion layer. The photoresist underlayer can include one or more of silicon and a metal. For example, the photoresist underlayer can include one or more of silicon oxide, silicon oxycarbide, silicon nitride, silicon oxynitride, silicon carbon nitride, silicon oxygen carbon nitride, metal oxide, metal nitride, metal oxycarbide, metal oxynitride, metal oxygen carbon nitride, and metal carbon nitride. When the photoresist underlayer comprises silicon, the same or a different silicon precursor can be used to form the photoresist underlayer and the adhesion layer.

The photoresist underlayer can be formed using a second cyclic deposition process, such as a plasma-enhanced cyclic (e.g., atomic layer) deposition process or a thermal cyclic deposition process. The photoresist underlayer can have a thickness of less than 10 nm or less than 5 nm. The photoresist layer can be or include, for example, positive or negative tone extreme ultraviolet (EUV) lithography photoresist.

In accordance with additional exemplary embodiments of the disclosure, a structure that includes a photoresist underlayer and an adhesion layer is provided. The photoresist underlayer and/or adhesion layer can be formed using a method as described herein. The photoresist underlayer can include, for example, a layer comprising a metal and/or silicon. The adhesion layer can include silicon. The adhesion layer can have surface energy properties as described herein. Exemplary structures can also include a layer of photoresist, such as negative tone or positive tone EUV photoresist.

In accordance with further examples of the disclosure, a system for forming an adhesion layer is provided. Exemplary systems include a reaction chamber, a silicon precursor source fluidly coupled to the reaction chamber, an inert gas source fluidly coupled to the reaction chamber, and a controller configured to perform a method as described herein or a portion thereof.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with exemplary embodiments of the disclosure.

FIG. 2 illustrates a method in accordance with exemplary embodiments of the disclosure.

FIG. 3 illustrates a structure in accordance with exemplary embodiments of the disclosure.

FIG. 4 illustrates another structure in accordance with exemplary embodiments of the disclosure.

FIG. 5 illustrates a system configured for executing a method as described herein.

FIG. 6 illustrates a system in accordance with yet additional examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood that the invention extends beyond the specifically disclosed embodiments and/or uses thereof and obvious modifications and equivalents thereof. Thus, it is intended that the scope of the invention disclosed should not be limited by the particular disclosed embodiments described below.

The present disclosure generally relates to methods of forming structures that include a photoresist underlayer and an adhesion layer and to structures including a photoresist underlayer and an adhesion layer. As described in more detail below, exemplary methods can be used to form structures with photoresist underlayers and adhesion layers that provide desired properties, such as desired photoresist underlayer thickness (e.g., less than 10 or less than 5 nm), relatively low surface roughness, good adhesion to the photoresist, desired etch selectivity, desired thickness uniformity—both within a substrate (e.g., a wafer) and between substrates, high pattern quality (low number of defects and high pattern fidelity), low line width roughness (LWR), photoresist stability during EUV lithography processing—e.g., during any post-exposure bake (PEB), photoresist development, reworking of the substrate, reasonable EUV sensitivity, and compatibility with integration (e.g., relatively low deposition temperatures).

As used herein, the term “substrate” may refer to any underlying material or materials including and/or upon which one or more layers can be deposited. A substrate can include a bulk material, such as silicon (e.g., single-crystal silicon), other Group IV materials, such as germanium, or compound semiconductor materials, such as GaAs, and can include one or more layers overlying or underlying the bulk material. For example, a substrate can include a patterning stack of several layers overlying bulk material. The patterning stack can vary according to application. Further, the substrate can additionally or alternatively include various features, such as recesses, lines, and the like formed within or on at least a portion of a layer of the substrate.

In some embodiments, “film” refers to a layer extending in a direction perpendicular to a thickness direction. In some embodiments, “layer” refers to a material having a certain thickness formed on a surface or a synonym of film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. Further, a layer or film can be continuous or discontinuous.

In this disclosure, “gas” may include material that is a gas at normal temperature and pressure, a vaporized solid and/or a vaporized liquid, and may be constituted by a single gas or a mixture of gases, depending on the context. A gas other than the process gas, i.e., a gas introduced without passing through a gas distribution assembly, such as a showerhead, other gas distribution device, or the like, may be used for, e.g., sealing the reaction space, and may include a seal gas, such as a rare gas.

In some cases, such as in the context of deposition of material, the term “precursor” can refer to a compound that participates in the chemical reaction that produces another compound, and particularly to a compound that constitutes a film matrix or a main skeleton of a film, whereas the term “reactant” can refer to a compound, in some cases other than precursors, that activates a precursor, modifies a precursor, or catalyzes a reaction of a precursor; a reactant may provide an element (such as O, N, C) to a film matrix and become a part of the film matrix. In some cases, the terms precursor and reactant can be used interchangeably. The term “inert gas” refers to a gas that does not take part in a chemical reaction to an appreciable extent and/or a gas that excites a precursor when, for example, RF or microwave power is applied, but unlike a reactant, it may not become a part of a film matrix to an appreciable extent.

The term “cyclic deposition process” or “cyclical deposition process” may refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

The term “atomic layer deposition” may refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of precursor(s)/reactive gas(es), and purge (e.g., inert carrier) gas(es).

Generally, for ALD processes, during each cycle, a precursor is introduced to a reaction chamber and is chemisorbed to a deposition surface (e.g., a substrate surface that can include a previously deposited material from a previous ALD cycle or other material), forming about a monolayer or sub-monolayer of material that does not readily react with additional precursor (i.e., a self-limiting reaction). Thereafter, in some cases, a reactant (e.g., another precursor or reaction gas or an inert gas) may subsequently be introduced into the process chamber for use in converting the chemisorbed precursor to the desired material on the deposition surface. The reactant/inert gas can be capable of further reaction or interaction with the precursor. Purging steps can be utilized during one or more cycles, e.g., during each step of each cycle, to remove any excess precursor from the process chamber and/or remove any excess reactant and/or reaction byproducts from the reaction chamber.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In accordance with aspects of the disclosure, any defined meanings of terms do not necessarily exclude ordinary and customary meanings of the terms.

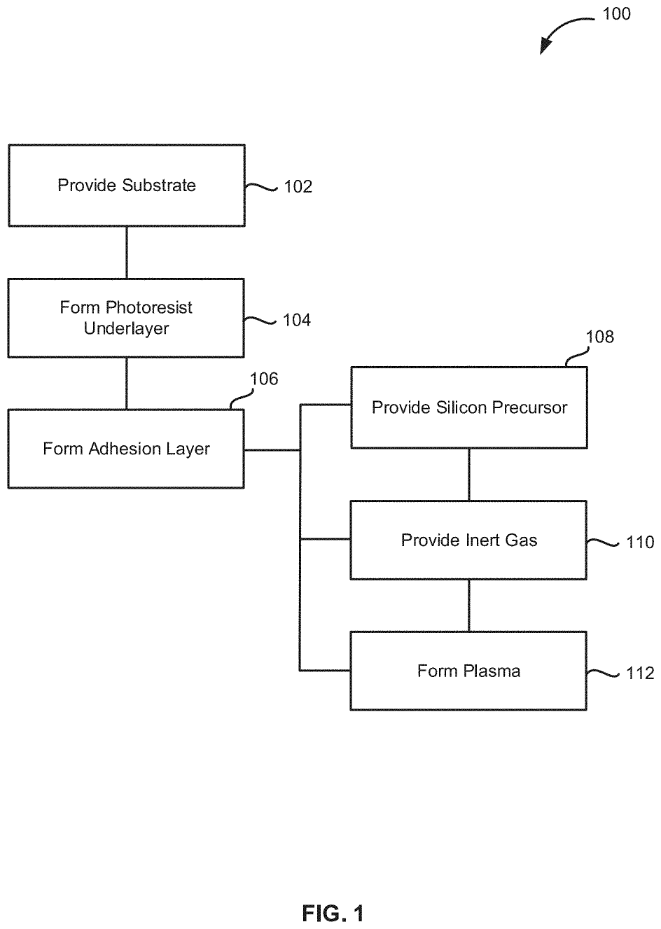

Turning now to the figures, FIG. 1 illustrates a method 100 in accordance with exemplary embodiments of the disclosure. Method 100 includes the steps of providing a substrate (step 102), forming a photoresist underlayer (step 104), and forming an adhesion layer (step 106).

Step 102 includes providing a substrate, such as a substrate described herein. The substrate can include one or more layers, including one or more material layers, to be etched. By way of examples, the substrate can include a deposited oxide, a native oxide, or an amorphous carbon layer to be etched. The substrate can include several layers underlying the material layer(s) to be etched.

During step 104, a photoresist underlayer is formed on a surface of the substrate. The photoresist underlayer can be formed using a variety of techniques, including spin-on, chemical vapor deposition, and cyclical process techniques. Plasma-processed SiO and SiOC materials have been identified as promising candidates for photoresist underlayer material due to their capabilities of continuously thinner thickness and lower dry etching rates compared with the conventional spin-on-glass (SoG). Typically, PEALD is suggested as a conceptually most promising method for a superior non-uniformity (% NU) of the film-thickness.

In accordance with exemplary aspects of method 100, the photoresist underlayer is formed using a cyclical deposition process, such as an ALD process—e.g., PEALD. The cyclical deposition process can include use of activated species (e.g., formed from one or more of precursor(s), reactant(s), or and/or inert gas(es)) that are formed using one or more of a direct plasma and a remote plasma. Alternatively, step 104 can include a thermal cyclical deposition process. Use of cyclical deposition processes may be desirable, because they allow for the formation of a photoresist underlayer with desired thickness—e.g., less than 10 nm or less than or about equal to 5 nm, with improved thickness uniformity—both within a substrate and from substrate-to-substrate. Using a plasma-enhanced process may be desirable, because plasma-enhanced processes allow for deposition of the photoresist underlayer material at relatively low temperatures and/or relatively high rates—compared to thermal processes.

In accordance with examples of the disclosure, a temperature within a reaction chamber during step 104 can be less than 500° C., less than 400° C., less than 300° C. or between about 100° C. and about 500° C., or about 150° C. and about 300° C. A pressure within the reaction chamber during step 104 can be about 1 Torr to about 100 Torr, about 3 Torr to about 50 Torr, or about 5 Torr to about 20 Torr.

In accordance with exemplary embodiments of the disclosure, step 104 includes forming or depositing one or more of a silicon or metal oxide, a silicon or metal nitride, and a silicon or metal oxynitride. Such oxides, nitrides, and/or oxynitrides can also include carbon.

The photoresist underlayer can include, for example, one or more of silicon oxide, silicon oxycarbide, silicon nitride, silicon oxynitride, silicon carbon nitride, silicon oxygen carbon nitride, metal oxide, metal nitride, metal oxycarbide, metal oxynitride, metal oxygen carbon nitride, and metal carbon nitride. The metal can include, for example, one or more metals selected from the group consisting of titanium, tantalum, tungsten, tin, and hafnium. In some cases, the photoresist underlayer includes carbon. The carbon can be incorporated into the photoresist underlayer as the photoresist underlayer is deposited and/or a carbon treatment can be applied to a surface of the photoresist underlayer. Additionally or alternatively, a carbon-containing layer or other layer can be deposited onto a surface of the photoresist underlayer. A thickness of the photoresist underlayer can be less than 10 nm, less than 5 nm, or greater than 3 and less than 10 nm.

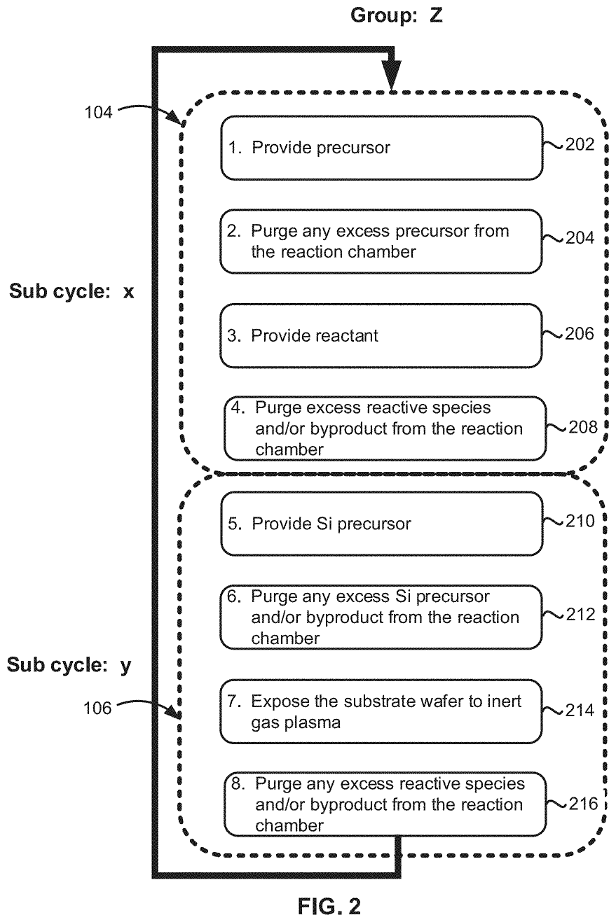

A cyclical process for forming the photoresist underlayer suitable for step 104 is illustrated in FIG. 2 (sub cycle x). Sub cycle x can include (A) pulsing a first precursor comprising a metal or silicon into a reaction chamber (step 202), and (B) pulsing a second precursor or reactant comprising an oxidant and/or nitriding agent into the reaction chamber (step 206). Sub cycle x can be repeated—e.g., between about 10 and about 50 or about 100 and about 200 times before method 100 proceeds to step 106.

In some cases, the cyclical process for forming the photoresist underlayer can include (A) pulsing a first precursor comprising a metal into a reaction chamber, (B) pulsing a second precursor or reactant comprising an oxidant and/or nitriding agent into the reaction chamber, and (C) pulsing a carbon precursor into the reaction chamber. Each of the pulses can be separated by a purge step (204, 208). Further, each pulsing step or a combination of pulsing steps (e.g., pulsing steps (A) and (B)) can be repeated a number of times prior to proceeding to the next step to tune a composition of the photoresist underlayer. For example, a range of ratios of (AB):C can be about 1:1 to about 1:10. Unless otherwise noted, steps (A) and (B) or steps (A), (B), and (C) can be performed in any order and various combinations of the steps can be repeated.

In accordance with exemplary aspects of the disclosure, a first precursor comprising silicon is provided. In some cases, the silicon precursor can also include carbon. Exemplary silicon precursors suitable for use in forming a photoresist underlayer include silicon precursors noted herein.

In accordance with other exemplary aspects of the disclosure, the first precursor comprises a metal. In these cases, the first precursor can include a transition metal, such as one or more metals selected from the group consisting of titanium, tantalum, tungsten, tin, and hafnium. The first precursor comprising a metal can also include carbon—e.g., one or more organic groups bonded directly or indirectly to a metal atom. By way of particular examples, the first precursor comprising a metal can include a metal halide or a metal organic compound, or an organometallic compound, such as one or more of tetrakis(dimethylamino)titanium (TDMAT), titanium isopropoxide (TTIP), titanium chloride (TiCl), tetrakis(ethylmethylamino)hafnium (TEMAHf), hafnium chloride (HfCl), trimethylaluminum (TMA), triethylaluminium (TEA), other metal halide, or other metal-containing compounds.

The reactant can include an oxidizing reactant, a nitriding reactant, or a reducing agent, such as a hydrogen-containing reactant. The oxidizing and/or nitriding reactant include reactants that include one or more of oxygen and nitrogen. In some cases, the reactant can include both nitrogen and oxygen. And, in some cases, the two or more oxidantsinzing and/or nitriding reactant can be included in a single pulse. Exemplary oxidizing and nitriding agents include oxygen (O₂), water (H₂O), ozone (O₃), hydrogen peroxide (H₂O₂), ammonia (NH₃), diazene (N₂H₂), CO₂, nitrous oxide (N₂O); exemplary hydrogen-containing reactants include hydrogen (H₂), and the like. As noted above, the oxidizing and/or nitriding reactant can be exposed to a (e.g., direct) plasma to form excited species for use in a PEALD process.

When used, the carbon precursor can include any suitable organic compound, such as compounds comprising carbon and oxygen. In some cases, the carbon precursor can also include nitrogen. The carbon precursor can be selected to react with, for example an —OH terminated surface of metal oxides and/or a —NH₂ terminated surface of a metal nitride. Examples of suitable carbon precursors include one or more of organic compounds, such as acid anhydrate (e.g., an acetic anhydrate), toluene, diethylene glycol, triethylene glycol, acetaldehyde, and organosilicon compounds, such as silanes, and siloxanes. Exemplary organosilicon compounds include (n,n-dimethylamino)trimethylsilane, trimethoxy(octadecyl)silane, hexamethyldisilazane, trimethoxy(3,3,3-trifluoropropyl)silane, trimethoxyphenylsilane, trichloro(3,3,3-trifluoropropyl)silane and hexamethyldisilazane.

Once the photoresist underlayer is formed, an adhesion layer is formed during step 106. Step 106 can be performed in situ—within the same reaction chamber and without an air and/or a vacuum break.

As illustrated in FIG. 1, step 106 can include the substeps of providing a silicon precursor (step 108), providing an inert gas (step 110), and forming a plasma (step 112). Step 106 can include a cyclical deposition process, such as a PEALD process. For example, with reference to FIG. 2, step 106 can include pulsing a silicon precursor to a reaction chamber (step 210), allowing the silicon precursor to react with a surface of a substrate, purging any unreacted precursor and/or byproducts (step 212), providing an inert gas to the reaction chamber, and forming a plasma using the inert gas to form activated species that react with the silicon precursor or a derivative thereof to form the adhesion layer (step 214), and purging any excess reactive species and/or byproducts from the reaction chamber (step 216). As illustrated, sub cycle y can be repeated a number of times—e.g., between about 30 and about 40 or about 50 or about 60 or about 70 and about 120 times. The temperature and pressure during step 106 can be the same or similar for step 102 and/or 104. A thickness of the adhesion layer is greater than 0 and less than 2 nm.

During step 210, a silicon precursor is provided to the reaction chamber. In accordance with examples of the disclosure, the silicon precursor does not comprise nitrogen. N-free precursors can be beneficial for use in forming an adhesion layer, because nitrogen is thought to exhibit a poisoning effect due to the presence of N atoms. In accordance with further examples, the silicon precursor consists of or consists essentially of Si, C, H, and O, which may be provided to the reaction chamber with the aid of a carrier gas. By way of examples, the silicon precursor can be selected from one or more of the group consisting of:

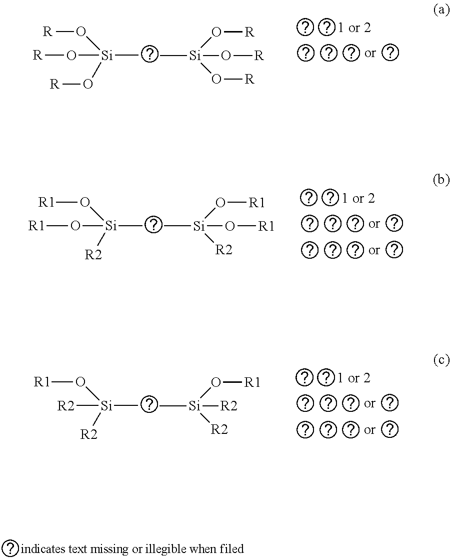

In accordance with further examples, the silicon precursor is selected from one or more of the group consisting of: 3-methoxypropyltrimethoxysilane, bis(trimethoxysilyl)methane, 1,2 bis(methyldimethoxysilyl)ethane, 1,2-bis(triethoxysilyl)ethane, 1,2-bis(triethoxysilyl)ethene, 1,2-bis(diethoxymethylsilyl)ethane, 1,2-bis(trimethoxysilyl)ethane, 1,1,3,3-tetra methoxy-1,3-disilacyclobutane, 1,1,3,3-tetraethoxy-1,3-disilacyclobutane, 1,1,3,3,5,5-hexamethoxy-1,3,5-trisilacyclohexane, 1,1,3,3,5,5-hexaethoxy-1,3,5-trisilacyclohexane. By way of particular example, the silicon precursor can be or include 3-methoxypropyltrimethoxysilane. A flowrate of the silicon precursor during step 210 can be between about 100 sccm and about 150 sccm. A duration of step 210 can be between about 0.1 s and about 0.3 s.

During step 212, any excess silicon precursor and/or any reaction byproducts can be purged from the reaction chamber. The purge can be performed by supplying an inert gas to the reaction chamber and/or using a vacuum source.

During step 214, a plasma is formed using an inert gas. The inert gas can be or include one or more of Ar, He, Ne, Kr, and Xe. A power to form the plasma can be about 30 W to about 1000 W. A frequency of the power to form the plasma can be between about 200 kHz and about 2.45 GHz. A flowrate of the inert gas can be between about 2 slm and about 10 slm. A duration of step 214 can be between about 0.1 s and about 2 s.

During step 216, the plasma power is switched-off and any excess reactive species and/or byproducts are purged. Sub cycle y can be repeated a number of times to form a silicon-based adhesion layer of a desired thickness—e.g., greater than 0 and less than about 2 nm.

Methods in accordance with the disclosure can also include a step of forming a photoresist layer overlying and in contact with the adhesion layer. The photoresist can be deposited using, for example, spin-on techniques. The photoresist layer can be or include positive or negative tone extreme ultraviolet (EUV) lithography photoresist.

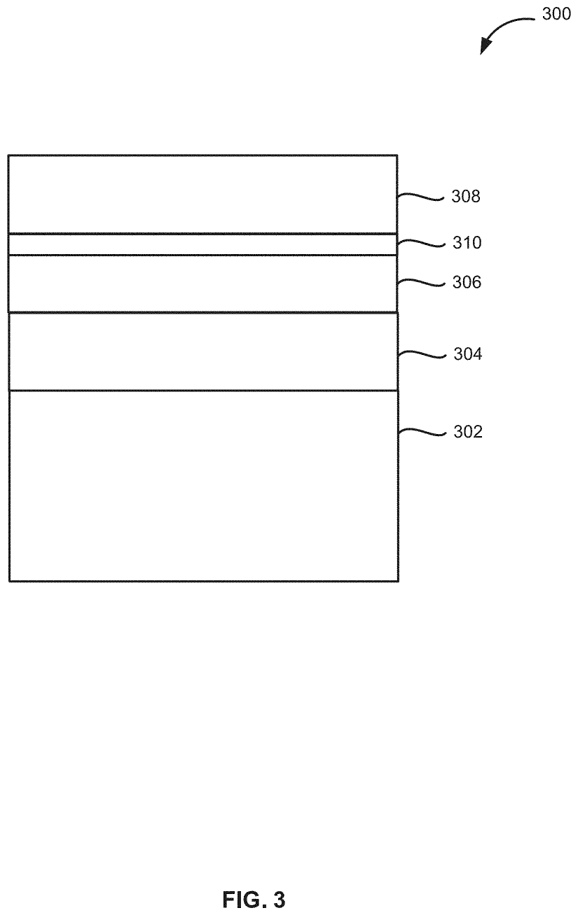

FIG. 3 illustrates a structure 300 in accordance with exemplary embodiments of the disclosure. Structure 300 can be formed using, for example, method 100 and/or 200.

As illustrated, structure 300 includes a substrate 302, a material layer 304, a photoresist underlayer 306, a photoresist layer 308, and an adhesion layer 310 interposed between and in contact with photoresist underlayer 306 and photoresist layer 308.

Substrate 302 can include a substrate as described above. By way of examples, substrate 302 can include a semiconductor substrate, such as a bulk material, such as silicon (e.g., single-crystal silicon), other Group IV semiconductor material, Group III-V semiconductor material, and/or Group II-VI semiconductor material and can include one or more layers (e.g., a patterning stack) overlying the bulk material. Further, as noted above, substrate 302 can include various topologies, such as recesses, lines, and the like formed within or on at least a portion of a layer of the substrate.

Material layer 304 can be patterned and etched using a photoresist underlayer and a layer of photoresist as described herein. Exemplary materials suitable for material layer 304 include, for example, oxides, such as native oxides or field oxides. Other exemplary material layer 304 materials include amorphous carbon, nitrides, other oxides, silicon, and add-on films (e.g., a self-assembled monolayer (e.g., hexamethyldisilazane (HMDS)).

Photoresist underlayer 306 can include a photoresist underlayer formed in accordance with a method described herein (e.g., method 100) and/or have properties and/or material as described herein. Exemplary photoresist underlayers include one or more of a silicon or metal oxide, a silicon or metal nitride, and a silicon or metal oxynitride—any of which can include or not include carbon. For example, photoresist underlayer 306 can include one or more of silicon oxide, silicon oxycarbide, silicon nitride, silicon oxynitride, silicon carbon nitride, silicon oxygen carbon nitride, metal oxide, metal nitride, metal oxycarbide, metal oxynitride, metal oxygen carbon nitride, and metal carbon nitride.

A thickness of photoresist underlayer 306 can depend on a composition of material layer 304, a thickness of material layer 304, a type of photoresist, and the like. In accordance with examples of the disclosure, photoresist underlayer 306 has a thickness of less than 10 nm or less than or about 5 nm or between about 3 nm and about 10 nm. If photoresist underlayer 306 is too thick, residual underlayer material may remain after an etch step. If photoresist underlayer 306 is too thin, photoresist underlayer 306 may not provide desired pattern transfer during an etch process.

Adhesion layer 310 desirably exhibits good adhesion and other properties as described herein. In accordance with examples of the disclosure, adhesion layer 310 includes silicon and can optionally include one or more of carbon, hydrogen, and oxygen. As noted above, adhesion layer 310 may desirably not include nitrogen.

To provide desired adhesion between photoresist layer 308 and photoresist underlayer 306, adhesion layer 310 may have or be tuned to have desired surface chemistry properties, e.g., quantified as surface energy, which is further categorized into a polar part of surface energy and a disperse part of surface energy. The polar part of surface energy and the disperse part of surface energy of photoresist underlayer 306 can be calculated by measuring a contact angle of a liquid, such as water or CH₂I₂, and using the Owens, Wendt, Rabel and Kaelble (OWRK) method to determine the polar part and the disperse part of the surface energy. The same properties can be measured and calculated for photoresist layer 308. A thickness of adhesion layer 310 can be greater than 0 nm and less than 2 nm.

In accordance with various examples of the disclosure, a value of a polar part of surface energy of adhesion layer 310 is between about 5 mN/m to about 25 mN/m or about 20 mN/m to about 40 mN/m. In accordance with further examples, a value of a dispersive part of surface energy of adhesion layer 310 is between about 10 mN/m to about 30 mN/m, or about 5 mN/m to about 25 mN/m, or about 20 mN/m to about 40 mN/m. For example, when photoresist layer 308 comprises negative tone photoresist, a value of the polar part of surface energy of the photoresist underlayer can be between about 20 mN/m and about 40 mN/m and/or a dispersive part of surface energy of the photoresist underlayer can be between about 10 mN/m to about 30 mN/m or about 20 mN/m to about 40 mN/m. When photoresist layer 308 includes positive tone photoresist, a value of the polar part of surface energy of the photoresist underlayer can be between about 5 mN/m to about 25 mN/m and/or a value of the dispersive part of surface energy of the photoresist underlayer can be between about 10 mN/m to about 30 mN/m.

By way of examples, with the utilization of an inert gas plasma to form adhesion layer 310, dangling bonds potentially behave as the surface reactive sites and lead to the chemisorption when the silicon precursor is introduced onto the film. Hence, ligands (e.g., CHx ligands) in the silicon precursor structure can eventually remain on the surface, which results in a desired surface free energy. The adhesive layer can be intrinsically SiOC, ending up with surface hydrocarbons.

Photoresist layer 308 can be or include positive or negative tone (e.g., EUV) photoresist.

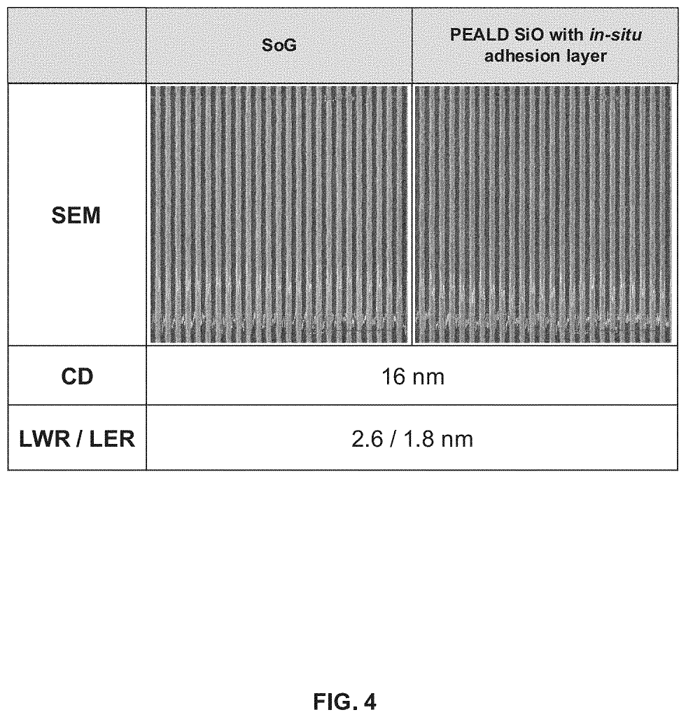

FIG. 4 illustrates scanning electron microscopy (SEM) images of patterned photoresist formed overlying spin-on glass and patterned photoresist formed overlying a PEALD silicon oxide layer with an adhesion layer as described herein. The PEALD silicon oxide layer is about 4 nm thick (formed using about 50 deposition cycles) and the adhesion layer is about 1 nm (formed with about 100 adhesion layer cycles). A full range % non uniformity (NU) was 1.5% and there were no defects (pattern collapse, micro-bridges, and micro-breaks) in CD 16 nm for the structure that included the adhesion layer. Moreover, the line width roughness (LWR) and line edge roughness (LER) were as good as the 10 nm SoG.

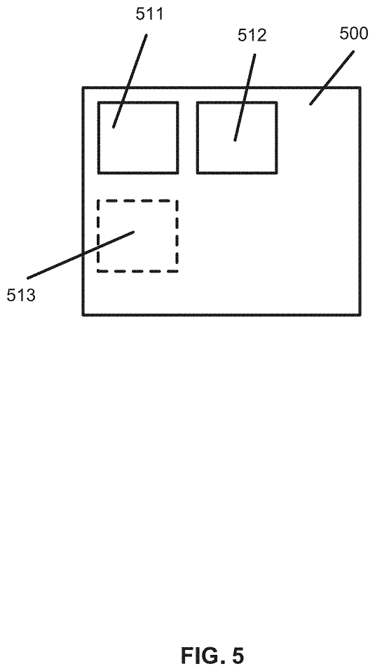

Further described, now referring to FIG. 5, is a system 500 configured for executing a method as described herein. System 500 comprises at least one reaction chamber which is configured for depositing an underlayer and forming an adhesion layer as described herein. System 500 may comprise a first reaction chamber 511 and a second reaction chamber 512 that may both be configured for depositing an underlayer and forming an adhesion layer as described herein, or a part thereof. If desired, system 500 can include a third reaction chamber 513 in which another process, such as a thermal or plasma-enhanced post treatment may be carried out.

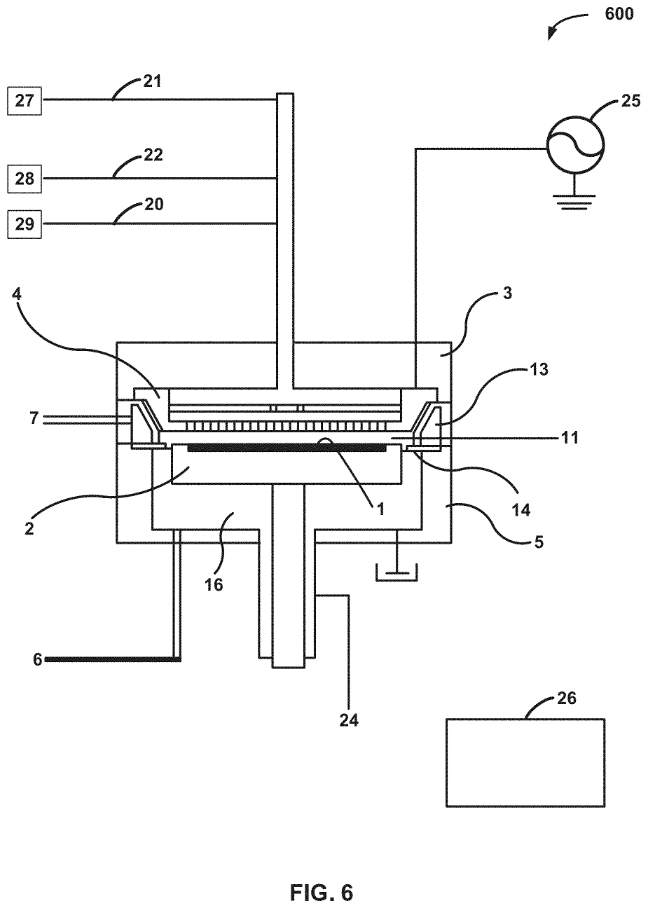

FIG. 6 illustrates an exemplary reaction chamber (e.g., suitable for use as reaction chamber 511 or 512) in greater detail. Reactor system 600 can be used to perform one or more steps or sub steps as described herein and/or to form one or more structures or portions thereof as described herein.

Reactor system 600 includes a pair of electrically conductive flat-plate electrodes 4, 2 in parallel and facing each other in the interior 11 (reaction zone) of a reaction chamber 3. A plasma can be excited within reaction chamber 3 by applying, for example, HRF power (e.g., 13.56 MHz or 27 MHz) from power source 25 to one electrode (e.g., electrode 4) and electrically grounding the other electrode (e.g., electrode 2). A temperature regulator can be provided in a lower stage 2 (the lower electrode), and a temperature of a substrate 1 placed thereon can be kept at a desired temperature. Electrode 4 can serve as a gas distribution device, such as a shower plate. Reactant gas, dilution gas, if any, precursor gas, and/or the like can be introduced into reaction chamber 3 using one or more of a gas line 20, a gas line 21, and a gas line 22, respectively, and through the shower plate 4. Although illustrated with three gas lines, reactor system 600 can include any suitable number of gas lines. Gas line 20 can be coupled to a silicon precursor source 29, gas line 21 can be coupled to an inert gas source 27, and gas line 22 can be coupled to another (e.g., reactant) gas source 28.

In reaction chamber 3, a circular duct 13 with an exhaust line 7 is provided, through which gas in the interior 11 of the reaction chamber 3 can be exhausted. Additionally, a transfer region 5, disposed below the reaction chamber 3, is provided with a seal gas line 24 to introduce seal gas into the interior 11 of the reaction chamber 3 via the interior 16 (transfer zone) of the transfer region 5, wherein a separation plate 14 for separating the reaction zone and the transfer zone is provided (a gate valve through which a wafer is transferred into or from the transfer region 5 is omitted from this figure). The transfer region is also provided with an exhaust line 6. In some embodiments, the deposition and treatment steps are performed in the same reaction space, so that two or more (e.g., all) of the (e.g., deposition and adhesion layer) steps can continuously be conducted without exposing the substrate to air or other oxygen-containing atmosphere.

In some embodiments, continuous flow of an inert or carrier gas to reaction chamber 3 can be accomplished using a flow-pass system (FPS), wherein a carrier gas line is provided with a detour line having a precursor reservoir (bottle), and the main line and the detour line are switched, wherein when only a carrier gas is intended to be fed to a reaction chamber, the detour line is closed, whereas when both the carrier gas and a precursor gas are intended to be fed to the reaction chamber, the main line is closed and the carrier gas flows through the detour line and flows out from the bottle together with the precursor gas. In this way, the carrier gas can continuously flow into the reaction chamber and can carry the precursor gas in pulses by switching between the main line and the detour line, without substantially fluctuating pressure of the reaction chamber.

Reactor system 600 also includes one or more controller(s) 26 programmed or otherwise configured to cause one or more method steps as described herein to be conducted. Controller(s) 26 are communicated with the various power sources, heating systems, pumps, robotics and gas flow controllers, or valves of the reactor, as will be appreciated by the skilled artisan. By way of examples, controller 26 can be configured to control gas flow of a silicon precursor and an inert gas to form an adhesion layer on a photoresist underlayer. Additionally or alternatively, the controller can be configured to perform steps to form a photoresist underlayer as described herein.

In some embodiments, a dual chamber reactor (two sections or compartments for processing wafers disposed close to each other) can be used, wherein a reactant gas and a noble gas can be supplied through a shared line, whereas a precursor gas is supplied through unshared lines.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to the embodiments shown and described herein, such as alternative useful combinations of the elements described, may become apparent to those skilled in the art from the description. Such modifications and embodiments are also intended to fall within the scope of the appended claims.

We claim:

1. A method of forming a structure comprising a photoresist underlayer, the method comprising the steps of:
providing a substrate within a reaction chamber;
forming a photoresist underlayer overlying a surface of the substrate; and
forming an adhesion layer using a first cyclic deposition process overlying the photoresist underlayer, the steps of forming the adhesion layer comprising:
providing a silicon precursor to the reaction chamber;
providing an inert gas into the reaction chamber; and
forming a plasma using the inert gas to form activated species that react with the silicon precursor or a derivative thereof to form the adhesion layer.

2. The method of claim 1, wherein the photoresist underlayer comprises one or more of silicon oxide, silicon oxycarbide, silicon nitride, silicon oxynitride, silicon carbon nitride, silicon oxygen carbon nitride, metal oxide, metal nitride, metal oxycarbide, metal oxynitride, metal oxygen carbon nitride, and metal carbon nitride.

3. The method of claim 2, wherein the metal comprises one or more metals selected from the group consisting of titanium, tantalum, tungsten, tin, and hafnium.

4. The method of claim 1, further comprising a step of forming a photoresist layer overlying and in contact with the adhesion layer, wherein the photoresist layer comprises extreme ultraviolet (EUV) lithography photoresist.

5. The method of claim 1, wherein a thickness of the photoresist underlayer is greater than 3 and less than 10 nm.

6. The method of claim 1, wherein the first cyclic deposition process is an atomic layer deposition process.

7. The method of claim 1, wherein the silicon precursor does not comprise nitrogen.

8. The method of claim 1, wherein the silicon precursor is selected from one or more of the group consisting of:

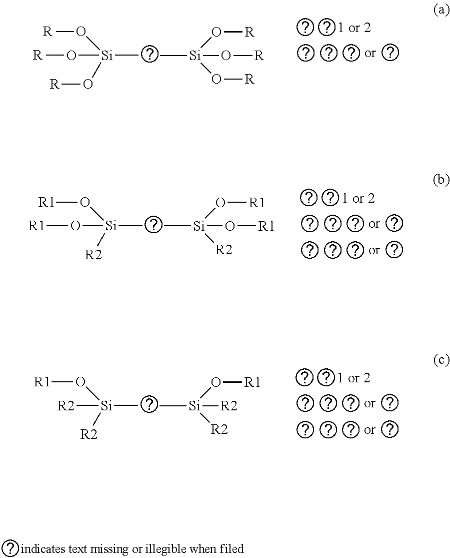

9. The method of claim 1, wherein the silicon precursor is selected from one or more of the group consisting of: 3-methoxypropyltrimethoxysilane, bis(trimethoxysilyl)methane, 1,2 bis(methyldimethoxysilyl)ethane, 1,2-bis(triethoxysilyl)ethane, 1,2-bis(triethoxysilyl)ethene, 1,2-bis(diethoxymethylsilyl)ethane, 1,2-bis(trimethoxysilyl)ethane, 1,1,3,3-tetramethoxy-1,3-disilacyclobutane, 1,1,3,3-tetraethoxy-1,3-disilacyclobutane, 1,1,3,3,5,5-hexamethoxy-1,3,5-trisilacyclohexane, 1,1,3,3,5,5-hexaethoxy-1,3,5-trisilacyclohexane.

10. The method of claim 1, wherein the photoresist underlayer is formed using a second cyclic deposition process.

11. The method of claim 1, wherein the photoresist underlayer is formed using the silicon precursor.

12. The method of claim 11, wherein a chemical formula of the silicon precursor consists of Si, C, H, and O.

13. The method of claim 1, wherein the first cyclic deposition process is repeated between about 30 and about 40 or about 50 or about 60 or about 70 and about 120 times.

14. The method of claim 1, wherein a thickness of the adhesion layer is greater than 0 nm and less than 2 nm.

15. The method of claim 1, wherein the second cyclic deposition process is repeated between about 10 and about 50 or about 100 and about 200 times.

16. A structure formed according to the method of claim 1.

17. The structure of claim 16, wherein the photoresist underlayer comprises one or more of silicon oxide, silicon oxycarbide, silicon nitride, silicon oxynitride, silicon carbon nitride, silicon oxygen carbon nitride, metal oxide, metal nitride, metal oxycarbide, metal oxynitride, metal oxygen carbon nitride, and metal carbon nitride.

18. The structure of claim 16, wherein the adhesion layer comprises silicon.

19. The structure of claim 16, further comprising EUV photoresist overlying and in contact with the adhesion layer.

20. A system for forming an adhesion layer, the system comprising:
a reaction chamber;
a silicon precursor source fluidly coupled to the reaction chamber;
an inert gas source fluidly coupled to the reaction chamber; and
a controller configured to perform the method according to claim 1.
